(19) United States
(12) Patent Application Publication
(10) Pub. No.: US 2026/0304710 A1
(43) Pub. Date: Oct. 1, 2026

(54) SERVER DEVICE, EXPANSION ASSEMBLY AND COOLING ASSEMBLY

(71) Applicant: WISTRON CORP., New Taipei City (TW)

(72) Inventors: CHIA PENG YANG, New Taipei City (TW); YU WEI LIN, New Taipei City (TW); JUN YU CHEN, New Taipei City (TW)

(21) Appl. No.: 19/250,237

(22) Filed: Jun. 26, 2025

(30) Foreign Application Priority Data
Mar. 28, 2025 (TW) 114112087

(51) Int. Cl. H05K 7/20

(52) U.S. Cl. CPC H05K 7/20772; H05K 7/20254

(57) ABSTRACT

A server device includes a casing, a first cold plate and an expansion assembly. The first cold plate is located in the casing. The expansion assembly is located in the casing, and includes a second cold plate, a third cold plate, a heat generating component and a power distribution unit. The second cold plate and third cold plate are mounted on the first cold plate, and are in fluid communication with the first cold plate. The third cold plate is located between the first cold plate and the second cold plate. The heat generating component is mounted on the second cold plate, and is located between the second cold plate and the third cold plate. The heat generating component is thermally coupled to the second cold plate and the third cold plate. The power distribution unit includes a first power distribution board disposed on the second cold plate.

### CROSS-REFERENCE TO RELATED APPLICATIONS

This non-provisional application claims priority under 35 U.S.C. § 119(a) on Patent Application No(s). 114112087 filed in Taiwan, R.O.C. on Mar. 28, 2025, the entire contents of which are hereby incorporated by reference.

### TECHNICAL FIELD

The present disclosure relates to a server device, an expansion assembly and a cooling assembly, more particularly to a server device, an expansion assembly and a cooling assembly relative to a heat generating component.

### BACKGROUND

Artificial Intelligence (AI) refers to enabling a server to learn from large amounts of data to simulate and exhibit human intelligence. As the amounts of information that the server can process (such as image and language data) is increasing, the development of artificial intelligence has accelerated accordingly.

Generally, in the server configured for artificial intelligence, the power distribution board (PDB) is disposed on a bottom side of the system on wafer (SoW). However, the aforementioned arrangement may result in an excessive stacking height of components within the server, thereby adversely affecting a space utilization within the server and reducing the efficiency for cooling the SoW. In addition, when a maintenance of the SoW is required, a cold plate and the wafer are required to be individually removed from the power distribution board, thereby complicating the maintenance process for the SoW.

### SUMMARY

The present disclosure provides a server device, an expansion assembly and a cooling assembly so as to improve the space utilization within the server and the cooling efficiency for cooling the heat generating component and simplify the maintenance process for the expansion assembly.

One embodiment of the present disclosure provides a server device including a casing, a first cold plate and an expansion assembly. The first cold plate is located in the casing. The expansion assembly is located in the casing, and includes a second cold plate, a third cold plate, a heat generating component and a power distribution unit. The second cold plate is detachably mounted on the first cold plate. The second cold plate is in fluid communication with the first cold plate. The third cold plate is detachably mounted on the first cold plate. The third cold plate is in fluid communication with the first cold plate. At least a portion of the third cold plate is located between the first cold plate and the second cold plate. The heat generating component is mounted on the second cold plate. The heat generating component is located between the second cold plate and the third cold plate. The heat generating component is thermally coupled to the second cold plate and the third cold plate. The power distribution unit includes a first power distribution board. The first power distribution board is disposed on the second cold plate.

Another embodiment of the present disclosure provides an expansion assembly configured to be disposed on a first cold plate. The expansion assembly includes a second cold plate, a third cold plate, a heat generating component and a power distribution unit. The second cold plate is configured to be detachably mounted on the first cold plate. The second cold plate is configured to be in fluid communication with the first cold plate. The third cold plate is configured to be detachably mounted on the first cold plate. The third cold plate is configured to be in fluid communication with the first cold plate. At least a portion of the third cold plate is configured to be located between the first cold plate and the second cold plate. The heat generating component is mounted on the second cold plate. The heat generating component is located between the second cold plate and the third cold plate. The heat generating component is thermally coupled to the second cold plate and the third cold plate. The power distribution unit includes a first power distribution board. The first power distribution board is disposed on the second cold plate.

Another embodiment of the present disclosure provides a cooling assembly configured to be disposed on a first cold plate and configured for a heat generating component to be disposed. The cooling assembly includes a second cold plate, a third cold plate and a power distribution unit. The second cold plate is configured to be detachably mounted on the first cold plate. The second cold plate is configured to be in fluid communication with the first cold plate. The third cold plate is configured to be detachably mounted on the first cold plate. The third cold plate is configured to be in fluid communication with the first cold plate. At least a portion of the third cold plate is configured to be located between the first cold plate and the second cold plate. The second cold plate and the third cold plate is configured to be thermally coupled to the heat generating component. The heat generating component is located between the second cold plate and the third cold plate. The power distribution unit includes a first power distribution board. The first power distribution board is disposed on the second cold plate.

According to the server device, the expansion assembly and the cooling assembly disclosed by the above embodiments, the second cold plate, the third cold plate, the heat generating component and the power distribution unit together configure the expansion assembly. Therefore, when the expansion assembly is required to be maintained, the entire expansion assembly can be directly removed from the first cold plate without individually removing the third cold plate, the heat generating component and the second cold plate. Accordingly, the maintenance process for the expansion assembly can be simplified.

In addition, compared to the conventional server device where the third cold plate in fluid communication with the second cold plate via a plurality of flow pipes to cause inconvenience of pipe management, in this embodiment, the server device replaces the flow pipes with the first cold plate. Accordingly, not only the pipe management is allowed to be omitted, but also the space utilization within the server device is improved.

Moreover, compared to the conventional server device where the power distribution board is disposed on a bottom side of a heat generating system, in this embodiment, the first power distribution board is disposed on the second cold plate. That is, the first power distribution board is disposed on a top side of the second cold plate, the third cold plate and the heat generating component so as to be disposed in an inverted configuration. Accordingly, the cooling fluid leaking from the first cold plate, the second cold plate or the third cold plate may be prevented from flowing onto the first power distribution board, thereby preventing the first power distribution board from being damaged by the leaking cooling fluid.

### BRIEF DESCRIPTION OF THE DRAWINGS

The present disclosure will become more fully understood from the detailed description given herein below and the accompanying drawings which are given by way of illustration only and thus are not limitative of the present disclosure and wherein:

FIG. 1 is a perspective view of a server device in accordance with the embodiment of the present disclosure;

FIG. 2 is an exploded view of the server device in FIG. 1;

FIG. 3 is an exploded view of a first cold plate and an expansion assembly of the server device in FIG. 1;

FIG. 4 is another exploded view of the first cold plate and the expansion assembly of the server device in FIG. 1;

FIG. 5 is a side view of the server device in FIG. 1; and

FIG. 6 is a schematic plane view showing that a cooling fluid flows in the server device in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

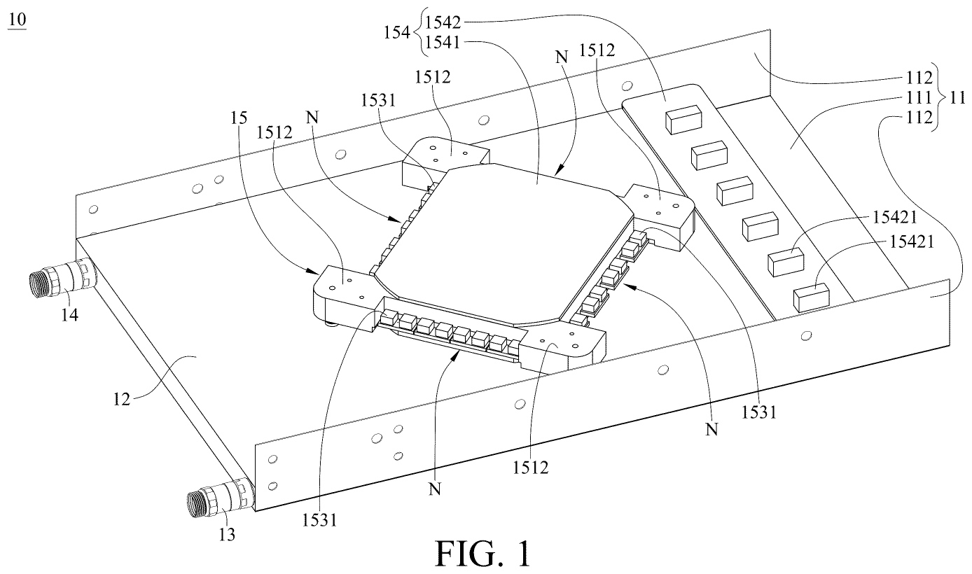

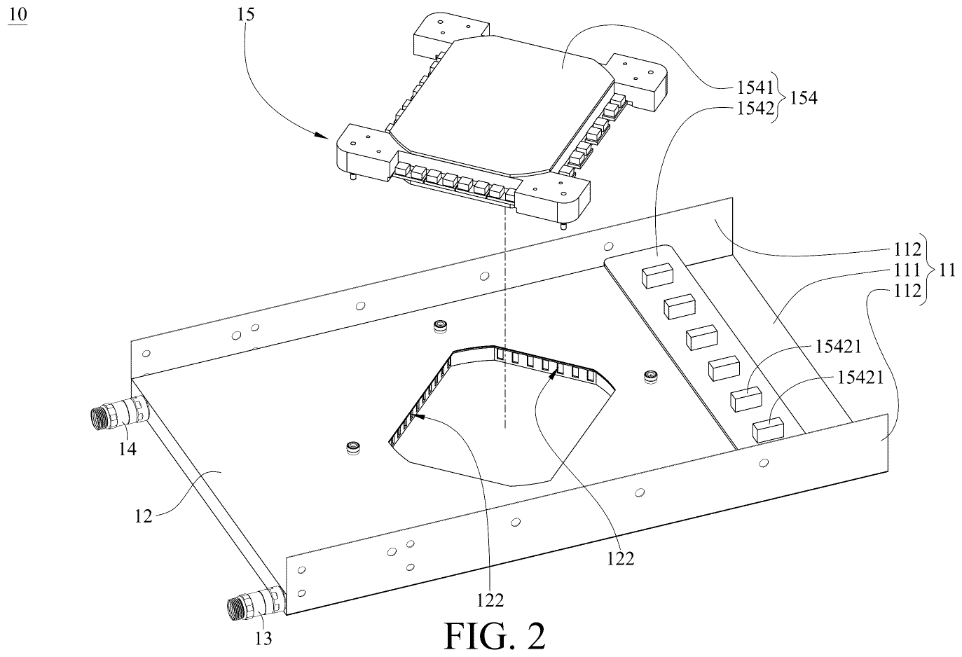

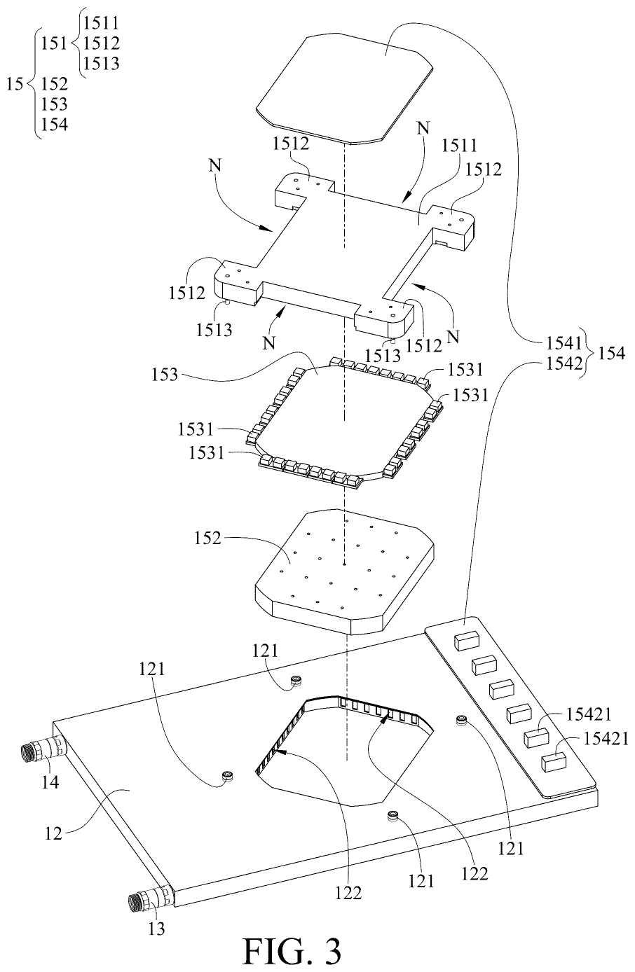

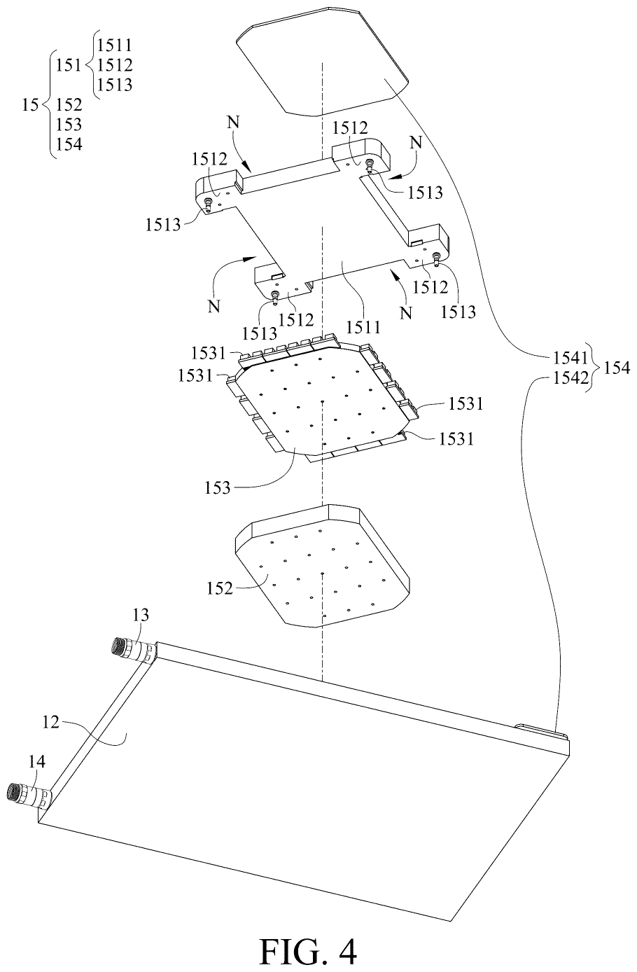

Please refer to FIG. 1 to FIG. 4, where FIG. 1 is a perspective view of a server device 10 in accordance with the embodiment of the present disclosure, FIG. 2 is an exploded view of the server device 10 in FIG. 1, FIG. 3 is an exploded view of a first cold plate 12 and an expansion assembly 15 of the server device 10 in FIG. 1, and FIG. 4 is another exploded view of the first cold plate 12 and the expansion assembly 15 of the server device 10 in FIG. 1.

In this embodiment, the server device 10 is, for example, an artificial intelligence server or a cloud server, and includes a casing 11, the first cold plate 12, an inlet pipe 13, an outlet pipe 14 and the expansion assembly 15. A height of the casing 11 is, for example, 2U. In detail, the casing 11 has a bottom plate 111 and two side plates 112. The two side plates 112 are connected to two opposite sides of the bottom plate 111 respectively

The first cold plate 12 is located in the casing 11, and is disposed on the bottom plate 111. For example, the first cold plate 12 is fastened to the casing 11 via screws (not shown). The first cold plate 12, for example, is approximately disposed throughout the entire bottom plate 111. In addition, the first cold plate 12 is made of, for example, a material having high thermal conductivity. For example, the first cold plate 12 is made of copper. The inlet pipe 13 and the outlet pipe 14 are in fluid communication with the first cold plate 12. The inlet pipe 13 is configured for a cooling fluid (not shown) to flow into the first cold plate 12. The outlet pipe 14 is configured for the cooling fluid to flow out of the first cold plate 12. The cooling fluid is, for example, water or refrigerant.

The expansion assembly 15 is located in the casing 11, and includes a second cold plate 151, a third cold plate 152, a heat generating component 153 and a power distribution unit 154. The second cold plate 151, the third cold plate 152 and the power distribution unit 154 together form a cooling assembly for cooling the heat generating component 153. The second cold plate 151 is detachably mounted on the first cold plate 12, and is in fluid communication with the first cold plate 12. In this embodiment, the first cold plate 12 includes four first quick release connectors 121. The second cold plate 151 includes a central portion 1511 and four corner portions 1512. The corner portions 1512 are connected to the central portion 1511. The second cold plate 151 includes four second quick release connectors 1513. The second quick release connectors 1513 are located on the corner portions 1512 respectively. The first cold plate 12 is in fluid communication with the second cold plate 151 via the first quick release connectors 121 and the second quick release connectors 1513.

In detail, an inner space of the first cold plate 12 is divided into two first flow channels (not shown). In addition, an inner space of the central portion 1511 is divided into two second flow channels (not shown). The first flow channels are not in fluid communication with each other, and the second flow channels are not in fluid communication with each other. One of the first flow channels, the first quick release connectors 121 and the second quick release connectors 1513 located on a side of the central portion 1511 and one of the second flow channels are in fluid communication with each other, and the other the first flow channel, the first quick release connectors 121 and the second quick release connectors 1513 located on another side of the central portion 1511 and the other second flow channel are in fluid communication with each other. That is, one of the first flow channels and one of the second flow channels form a closed circulation with corresponding ones of the first quick release connectors 121 and corresponding ones of the second quick release connectors 1513, and the other first flow channel and the other second flow channel form another closed circulation with corresponding ones of the first quick release connectors 121 and corresponding ones of the second quick release connectors 1513. Structures of the said two closed circulations are the same.

The third cold plate 152 is detachably mounted on the first cold plate 12, and the third cold plate 152 and the first cold plate 12 seal each other. At least a portion of the third cold plate 152 is, for example, embedded in the first cold plate 12. In detail, a portion of the first cold plate 12 where the third cold plate 152 is embedded has a plurality of openings 122. When the cooling fluid flows out of the first cold plate 12 through the openings 122, the cooling fluid can cool the third cold plate 152. In addition, since the third cold plate 152 and the first cold plate 12 seal each other, a leakage of the cooling fluid can be prevented. Moreover, at least a portion of the third cold plate 152 is located between the first cold plate 12 and the second cold plate 151. The first cold plate 12 is approximately disposed throughout the entire bottom plate 111, and the second cold plate 151 and the third cold plate 152 can be disposed on the first cold plate 12. However, the present disclosure is not limit thereto, as long as the size of the first cold plate 12 is sufficient for the second cold plate 151 and the third cold plate 152 to be disposed, the first cold plate 12 may be disposed throughout a part of the bottom plate 111 merely.

The heat generating component 153 is, for example, a wafer, and is mounted on the second cold plate 151. The heat generating component 153 is located between the second cold plate 151 and the third cold plate 152. The heat generating component 153 is thermally coupled to the second cold plate 151 and the third cold plate 152. That is, two opposite sides of the heat generating component 153 are cooled by the second cold plate 151 and the third cold plate 152 respectively. A cooling cycle is completed via the first cold plate 12, the inlet pipe 13, the outlet pipe 14, the second cold plate 151 and the third cold plate 152. A diameter of the heat generating component 153 is, for example, 12 inches. In addition, an area of the heat generating component 153 requiring high cooling capacity is cooled by the third cold plate 152.

In addition, the heat generating component 153 has a plurality of electrical connectors 1531. The electrical connectors 1531 are configured for a plurality of cables (not shown) to be plugged therein. The corner portions 1512 of the second cold plate 151 protrude from a peripheral contour of the central portion 1511. The electrical connectors 1531 are located between any two adjacent corner portions 1512 respectively. In detail, the second cold plate 151 has a plurality of notches N. The notches N are located between any two adjacent corner portions 1512 respectively. The electrical connectors 1531 are located at the notches N respectively. Accordingly, the electrical connectors 1531 are not interfered with the second cold plate 151. The electrical connectors 1531 are disposed on a plurality of circuit boards (not shown) respectively, and the circuit boards are connected to the heat generating component 153 via, for example, a surface mount technology (SMT).

The power distribution unit 154 is configured to distribute power, and includes a first power distribution board 1541 and a second power distribution board 1542. In detail, the second power distribution board 1542 is a board separated from the first power distribution board 1541. The first power distribution board 1541 is disposed on the central portion 1511 of the second cold plate 151. The first power distribution board 1541, the second cold plate 151, the heat generating component 153 and the third cold plate 152 are sequentially stacked along a direction from the first cold plate 12 to the first cold plate 12. That is, when the casing 11 is placed horizontally, the first power distribution board 1541, the second cold plate 151, the heat generating component 153 and the third cold plate 152 are sequentially stacked from top to bottom on the first cold plate 12 (e.g., along gravitational direction). Compared to the conventional server device where the power distribution board is disposed on a bottom side of a heat generating system, in this embodiment, the first power distribution board 1541 is disposed on a top side of the second cold plate 151, the third cold plate 152 and the heat generating component 153 so as to be disposed in an inverted configuration. In addition, the second cold plate 151 not only can be configured for the heat generating component 153 to be disposed, but also can cool the heat generating component 153 and the first power distribution board 1541. The first power distribution board 1541, the second cold plate 151, the third cold plate 152 and the heat generating component 153 are fastened to the first cold plate 12 via screws (not shown).

An area of the central portion 1511 covered by the first power distribution board 1541 is, for example, less than or equal to an area of the central portion 1511. That is, the first power distribution board 1541 does not cover the notches N. Accordingly, when the cables are plugged into or unplugged from the electrical connectors 1531 of the heat generating component 153, the cables and the electrical connectors 1531 may not be blocked by the first power distribution board 1541. That is, the cables and the electrical connectors 1531 are allowed to be seen directly. In addition, the electrical connectors 1531 are not interfered with the second cold plate 151. Therefore, the cables can be plugged or unplugged directly at the notches N without removing the second cold plate 151.

In addition, the first power distribution board 1541 has, for example, 400VDC hot swappable controller and fuse, a power supply, and a DC/DC power converter (not shown). The second power distribution board 1542 is disposed on the first cold plate 12, and has a plurality of power distribution components 15421. The power distribution components 15421 are, for example, configured to convert the 3.6 kW power supply from 400VDC to 50VDC, and to convert the DC/DC power converter from 48VDC to 12VDC.

In this embodiment, the second cold plate 151, the third cold plate 152, the heat generating component 153 and the power distribution unit 154 together form the expansion assembly 15. Therefore, when the expansion assembly 15 is required to be maintained, the entire expansion assembly 15 can be directly removed from the first cold plate 12 without individually removing the third cold plate 152, the heat generating component 153 and the second cold plate 151. Accordingly, the maintenance process for the expansion assembly 15 can be simplified.

In addition, compared to the conventional server device where the third cold plate in fluid communication with the second cold plate via a plurality of flow pipes to cause inconvenience of pipe management, in this embodiment, the server device 10 replaces the flow pipes with the first cold plate 12. Accordingly, not only the pipe management is allowed to be omitted, but also the space utilization within the server device 10 is improved.

Moreover, compared to the conventional server device where the power distribution board is disposed on a bottom side of a heat generating system, in this embodiment, the first power distribution board 1541 is disposed on the second cold plate 151. That is, the first power distribution board 1541 is disposed on a top side of the second cold plate 151, the third cold plate 152 and the heat generating component 153 so as to be disposed in an inverted configuration. Accordingly, the cooling fluid leaking from the first cold plate 12, the second cold plate 151 or the third cold plate 152 may be prevented from flowing onto the first power distribution board 1541, thereby preventing the first power distribution board 1541 from being damaged by the leaking cooling fluid.

Furthermore, the power distribution unit 154 includes the first power distribution board 1541 and the second power distribution board 1542, and the second power distribution board 1542 is the board separated from the first power distribution board 1541. Therefore, a thickness of the first power distribution board 1541 can be reduced, for example, by two to three times so as to improve the space utilization within the server device 10. In addition, heat generating components of the power distribution unit 154 can be arranged sparsely, such that the heat generating components of the power distribution unit 154 can be prevented from being overly concentrated near the heat generating component 153. The first power distribution board 1541 and the second power distribution board 1542 are cooled by the second cold plate 151 and the first cold plate 12 respectively. Accordingly, the efficiency for cooling the heat generating component 153 can be improved.

In this embodiment, there are multiple first quick release connectors 121, multiple second quick release connectors 1513 and four corner portions 1512, but the present disclosure is not limit thereto. In other embodiment, there may be one first quick release connector and one second quick release connector merely, and there may be less than or more than four corner portions.

In this embodiment, the area of the heat generating component 153 requiring high cooling capacity is cooled by the third cold plate 152, but the present disclosure is not limit thereto. In other embodiment, the area of the heat generating component requiring high cooling capacity may be cooled by the second cold plate.

In this embodiment, there are multiple power distribution components 15421, but the present disclosure is not limit thereto. In other embodiment, there may be one power distribution component merely.

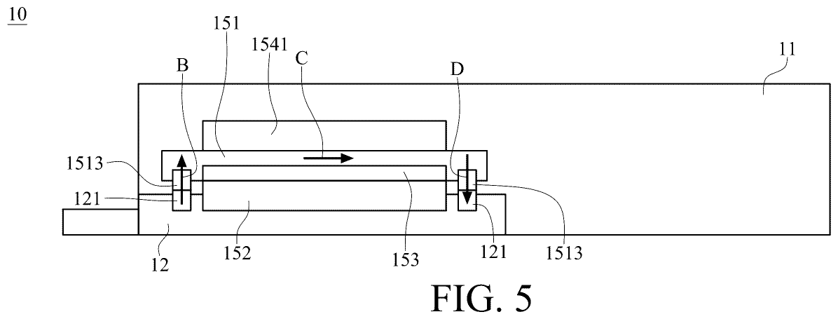

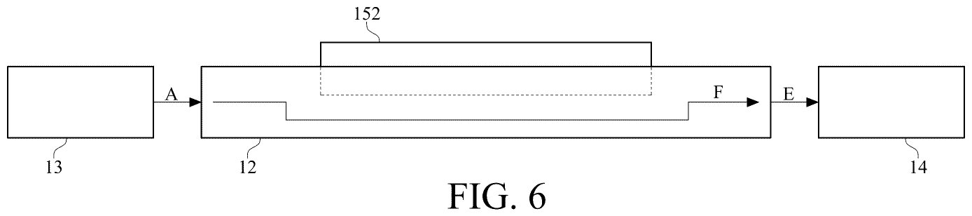

Please refer to FIG. 1 to FIG. 6, where FIG. 5 is a side view of the server device 10 in FIG. 1, and FIG. 6 is a schematic plane view showing that a cooling fluid flows in the server device 10 in FIG. 1.

In this embodiment, since the structures of the two closed circulations are the same, only one closed circulation will be described below. As shown in FIG. 6, the cooling fluid flows into the first cold plate 12 from the inlet pipe 13 along a direction A. Then, as shown in FIG. 5, the cooling fluid flows into the second cold plate 151 from the first cold plate 12 along a direction B via the first quick release connectors 121 and the second quick release connectors 1513. Then, the cooling fluid flows in the second cold plate 151 along a direction C. At this time, the heat generated by the heat generating component 153 and transferred to the second cold plate 151 is absorbed by the cooling fluid. Then, the cooling fluid absorbing the heat flows back to the first cold plate 12 from the second cold plate 151 along a direction D. Then, as shown in FIG. 6, the cooling fluid absorbing the heat flows out of the first cold plate 12 along a direction E via the outlet pipe 14, such that the next cooling cycle can be performed.

In addition, as shown in FIG. 6, the cooling fluid also flows along a direction F in the first cold plate 12 after flowing into the first cold plate 12. Then, the cooling fluid performs the heat exchange. In detail, the heat generated by the heat generating component 153 and transferred to the third cold plate 152 via the openings 122 is simultaneously absorbed by the cooling fluid.

According to the server device, the expansion assembly and the cooling assembly disclosed by the above embodiments, the second cold plate, the third cold plate, the heat generating component and the power distribution unit together configure the expansion assembly. Therefore, when the expansion assembly is required to be maintained, the entire expansion assembly can be directly removed from the first cold plate without individually removing the third cold plate, the heat generating component and the second cold plate. Accordingly, the maintenance process for the expansion assembly can be simplified.

In addition, compared to the conventional server device where the third cold plate in fluid communication with the second cold plate via a plurality of flow pipes to cause inconvenience of pipe management, in this embodiment, the server device replaces the flow pipes with the first cold plate. Accordingly, not only the pipe management is allowed to be omitted, but also the space utilization within the server device is improved.

Moreover, in the conventional server device, the power distribution board is disposed on a bottom side of a heat generating system. Compared to the aforementioned server device, in this embodiment, the first power distribution board is disposed on the second cold plate. That is, the first power distribution board is disposed on a top side of the second cold plate, the third cold plate and the heat generating component so as to form in an inverted configuration. Accordingly, the cooling fluid leaking from the first cold plate, the second cold plate or the third cold plate may not flow onto the first power distribution board, thereby preventing the first power distribution board from being damaged caused by leaking cooling fluid.

Furthermore, the power distribution unit includes the first power distribution board and the second power distribution board, and the second power distribution board is the board separated from the first power distribution board. Therefore, a thickness of the first power distribution board can be reduced, for example, by two to three times so as to improve the space utilization within the server device. In addition, heat generating components of the power distribution unit can be arranged sparsely, such that the heat generating components of the power distribution unit can be prevented from being overly concentrated near the heat generating component. The first power distribution board and the second power distribution board are cooled by the second cold plate and the first cold plate respectively. Accordingly, the efficiency for cooling the heat generating component can be improved.

It will be apparent to those skilled in the art that various modifications and variations can be made to the present disclosure. It is intended that the specification and examples be considered as exemplary embodiments only, with the scope of the present disclosure being indicated by the following claims.

What is claimed is:

1. A server device, comprising:
a casing;
a first cold plate, located in the casing; and
an expansion assembly, located in the casing, the expansion assembly comprising:
a second cold plate, detachably mounted on the first cold plate, wherein the second cold plate is in fluid communication with the first cold plate;
a third cold plate, detachably mounted on the first cold plate, wherein the third cold plate is in fluid communication with the first cold plate, and at least a portion of ( [symbol] a portion of) the third cold plate is located between the first cold plate and the second cold plate;
a heat generating component, mounted on the second cold plate, wherein the heat generating component is located between the second cold plate and the third cold plate, and the heat generating component is thermally coupled to the second cold plate and the third cold plate; and
a power distribution unit, comprising a first power distribution board, wherein the first power distribution board is disposed on the second cold plate.

2. The server device according to claim 1, wherein the casing has a bottom plate and two side plates, the two side plates are connected to two opposite sides of the bottom plate respectively, and the first cold plate is disposed on the bottom plate.

3. The server device according to claim 2, wherein at least a portion of the third cold plate is embedded in the first cold plate.

4. The server device according to claim 1, further comprising an inlet pipe and an outlet pipe, wherein the inlet pipe and the outlet pipe are in fluid communication with the first cold plate.

5. The server device according to claim 1, wherein the first cold plate has at least one first quick release connector, the second cold plate has at least one second quick release connector, and the first cold plate is in fluid communication with the second cold plate via the at least one first quick release connector and the at least one second quick release connector.

6. The server device according to claim 5, wherein the second cold plate comprises a central portion and at least one corner portion, the at least one corner portion is connected to the central portion, the first power distribution board covers the central portion, the at least one second quick release connector is located on the at least one corner portion, and an area of the central portion covered by the first power distribution board is less than or equal to an area of the central portion.

7. The server device according to claim 6, wherein the at least one first quick release connector comprises four first quick release connectors, the at least one second quick release connector comprises four second quick release connectors, the at least one corner portion comprises four corner portions, and the four second quick release connectors are located on the four corner portions respectively.

8. The server device according to claim 7, wherein the heat generating component has a plurality of electrical connectors, and the plurality of electrical connectors are located between any adjacent two of the plurality of corner portions respectively.

9. The server device according to claim 8, wherein the second cold plate has a plurality of notches, the plurality of notches are located between any adjacent two of the plurality of corner portions respectively, and the plurality of electrical connectors are located at the plurality of notches respectively.

10. The server device according to claim 1, wherein the power distribution unit further comprises a second power distribution board, the second power distribution board is disposed on the first cold plate, and the second power distribution board has at least one power distribution component.

11. An expansion assembly, configured to be disposed on a first cold plate, the expansion assembly comprising:
a second cold plate, configured to be detachably mounted on the first cold plate, wherein the second cold plate is configured to be in fluid communication with the first cold plate;
a third cold plate, configured to be detachably mounted on the first cold plate, wherein the third cold plate is configured to be in fluid communication with the first cold plate, and at least a portion of the third cold plate is configured to be located between the first cold plate and the second cold plate;
a heat generating component, mounted on the second cold plate, wherein the heat generating component is located between the second cold plate and the third cold plate, and the heat generating component is thermally coupled to the second cold plate and the third cold plate; and
a power distribution unit, comprising a first power distribution board, wherein the first power distribution board is disposed on the second cold plate.

12. The expansion assembly according to claim 11, wherein at least a portion of the third cold plate is configured to be embedded in the first cold plate.

13. The expansion assembly according to claim 11, wherein the second cold plate has at least one second quick release connector, and the second cold plate is configured to be in fluid communication with the first cold plate via at least one first quick release connector of the first cold plate and the at least one second quick release connector.

14. The expansion assembly according to claim 13, wherein the second cold plate comprises a central portion and at least one corner portion, the at least one corner portion is connected to the central portion, the first power distribution board covers the central portion, the at least one second quick release connector is located on the at least one corner portion, and an area of the central portion covered by the first power distribution board is less than or equal to an area of the central portion.

15. The expansion assembly according to claim 14, wherein the at least one first quick release connector comprises four first quick release connectors, the at least one second quick release connector comprises four second quick release connectors, the at least one corner portion comprises four corner portions, and the four second quick release connectors are located on the four corner portions respectively.

16. The expansion assembly according to claim 15, wherein the heat generating component has a plurality of electrical connectors, and the plurality of electrical connectors are located between any adjacent two of the plurality of corner portions respectively.

17. The expansion assembly according to claim 11, wherein the power distribution unit further comprises a second power distribution board, the second power distribution board is configured to be disposed on the first cold plate, and the second power distribution board has at least one power distribution component.

18. A cooling assembly, configured to be disposed on a first cold plate and configured for a heat generating component to be disposed, the cooling assembly comprising:
a second cold plate, configured to be detachably mounted on the first cold plate, wherein the second cold plate is configured to be in fluid communication with the first cold plate;
a third cold plate, configured to be detachably mounted on the first cold plate, wherein the third cold plate is configured to be in fluid communication with the first cold plate, at least a portion of the third cold plate is configured to be located between the first cold plate and the second cold plate, the second cold plate and the third cold plate is configured to be thermally coupled to the heat generating component, and the heat generating component is located between the second cold plate and the third cold plate; and
a power distribution unit, comprising a first power distribution board, wherein the first power distribution board is disposed on the second cold plate.

19. The cooling assembly according to claim 18, wherein the second cold plate has at least one second quick release connector, and the second cold plate is configured to be in fluid communication with the first cold plate via at least one first quick release connector of the first cold plate and the at least one second quick release connector.

20. The cooling assembly according to claim 18, wherein the power distribution unit further comprises a second power distribution board, the second power distribution board is configured to be disposed on the first cold plate, and the second power distribution board has at least one power distribution component.
